(19) United States
(12) Patent Application Publication
(10) Pub. No.: US 2025/0006744 A1
(43) Pub. Date: Jan. 2, 2025

(54) SEMICONDUCTOR STRUCTURE

(71) Applicant: Invention and Collaboration Laboratory, Inc., Taipei City (TW)

(72) Inventor: Chao-Chun Lu, Taipei City (TW)

(73) Assignee: Invention and Collaboration Laboratory, Inc., Taipei City (TW)

(21) Appl. No.: 18/757,552

(22) Filed: Jun. 28, 2024

Related U.S. Application Data
(60) Provisional application No. 63/523,645, filed on Jun. 28, 2023.

(51) Int. Cl. H01L 27/12; H01L 21/762; H01L 29/06

(52) U.S. Cl. CPC H01L 27/1207; H01L 29/0692; H01L 21/7624

(57) ABSTRACT

A semiconductor structure includes a semiconductor substrate, a semiconductor island, a shallow trench isolation (STI) region, a first buried layer, and a second buried layer. The semiconductor substrate has an original surface. The semiconductor island is formed based on the semiconductor substrate. The shallow trench isolation (STI) region surrounds the semiconductor island. The first buried layer is a localized layer under the semiconductor island, wherein a material of the first buried layer is different from that of the semiconductor substrate. The second buried layer is a localized layer under the first buried layer, wherein a material of the second buried layer is different from that of the semiconductor substrate.

### CROSS REFERENCE TO RELATED APPLICATIONS

This application claims the benefit of U.S. Provisional Application No. 63/523,645, filed on Jun. 28, 2023. The content of the application is incorporated herein by reference.

### BACKGROUND OF THE INVENTION

### 1. Field of the Invention

The present invention relates to a semiconductor structure, especially to an insulated or functional semiconductor structure implemented by using less expensive bulk silicon wafer substrate instead of using an entire silicon On Insulator (SOI) wafer that is more expensive.

### 2. Description of the Prior Art

At present silicon Integrated Circuits (IC) industry can integrate more than billions of transistors in a silicon die. Most ICs are built in “bulk” silicon substrate wafers. Such a term “bulk” usually means that a common silicon substrate material is used to hold all transistors which are built into it by monolithic fabrication methods and the body of transistors are usually connected and biased at a common substrate voltage (e.g. N-type MOSFET (metal-oxide-semiconductor filed effect transistor) in a p-well and PMOS in an n-well inside a bulk substrate).

In contrast to using a bulk silicon wafer, there is so-called “SOI” substrate. The state-of-the-art SOI (silicon On Insulator) transistor is made in a silicon substrate based on an early-prepared entire SOI wafer for some specialty applications since it is more expensive than the bulk transistor manufactured in a substrate which is connected to an entire bulk-type silicon wafer (which is more commonly used for manufacturing most integrated circuits). The major disadvantage of the SOI transistor technology is that the cost per each transistor made in an SOI wafer is much higher than that made in a bulk silicon wafer. This causes that the cost reduction per each SOI-transistor generation is hard to meet the stringent demand on the cost reduction per bit as dictated by Moore's Law, and so the existing SOI technology does not become a mainstream commodity process technology which has been dominated by the bulk-silicon-substrate technology. The SOI technology is still demanded due to its high performance advantages in some specialty applications such as for high frequency, low noise, radiation-hard or microwave devices, however.

Several novel methods have been developed for preparing an entire SOI wafer; for example, (1) By bonding together two wafers each of which has a silicon-dioxide layer covered on the surface of a bulk-substrate wafer, respectively, and then by flipping one wafer on the other wafer and due to mutual oxide molecular binding forces, these two wafers can be well connected due to these two layers of oxide, which results in a layer of oxide to be sandwiched between these two oxide-covered bulk wafers; afterwards one wafer is ground down to a specific thickness to create an SOI wafer having a single-crystalline silicon layer on top of an oxide layer over a silicon wafer as the substrate carrier, or (2) The other formation method of an entire SOI wafer is to implant oxide atoms through the silicon wafer surface and to use thermal process to create an embedded silicon-Dioxide layer, that is, such a process results in a thin silicon film over an underlying silicon-Dioxide layer due to this implanted oxide layer embedded into the original silicon substrate wafer. Either method is used to create an entire SOI wafer but at much higher costs than that of using a bulk silicon wafer, especially for a wafer size with a large wafer diameter (e.g. 8″ or 12″). Afterwards the well-known silicon processing method can create the MOSFET (Metal-oxide-Semiconductor Field-Effect-Transistor) or even the BiCMOS circuits in such an entire SOI wafer.

For both bulk and SOI technologies the silicon wafer is used as the fundamental carrier material which is biased at a voltage, either Ground for the p-type wafer or VDD (a positive supply voltage) for the n-type wafer. In order to make better conductivity the backside of the wafer is polished and then put some metal layer over the backside.

Recently there is a strong need to make the wafer substrate thinner after the IC process is completed by some special “Thinning Technology”. For instance, the original wafer substrate may have its thickness like ˜300 to 500 micrometers, and the Thinning wafer substrate can be as thin as ˜50 micrometers. The challenge is how to carry such a Thinning wafer for subsequent assembly/packaging processes without cracking or breaking problems.

The present invention provides a method to structure a heterogeneous wafer substrate with more than silicon material so that a term “SOZ” is created to describe its generalized feature by using “Z” as a representative term for special material; for example, if SOI is needed with oxide as the substrate for transistors, then the present invention is referred to SOZ=SOI. But the Z can be a conductive material such as a metal like Tungsten W to serve some highly-demanded special functions like higher electrical conductivity, higher thermal conductivity and stronger supporter for Thinning wafer carriers, or an insulator like Diamond for higher thermal conductivity and mechanical support for Thinning substrate. The other new invention feature is that this Z material is inserted underneath the substrate original surface in a localized formation instead of using an entire wafer formation; for example, the SOZ (Z=oxide) is for an individual transistor without using an expensive entire SOI wafer in the state-of-the-art SOI technology. So the SOZ starts from a silicon bulk wafer and then form localized SOZ transistors (e.g. SOI devices, SO-Tungsten or SO-diamond devices, but the other devices could be still in the form of bulk transistors with a common connected substrate or serve as a deep junction-type ESD device, etc.

### SUMMARY OF THE INVENTION

An embodiment of the present invention provides a semiconductor structure. The semiconductor structure includes a semiconductor substrate, a semiconductor island, a shallow trench isolation (STI) region, a first buried layer, and a second buried layer. The semiconductor substrate has an original surface. The semiconductor island is formed based on the semiconductor substrate. The shallow isolation trench (STI) region surrounds the semiconductor island. The first buried layer is a localized layer under the semiconductor island, wherein a material of the first buried layer is different from that of the semiconductor substrate. The second buried layer is a localized layer under the first buried layer, wherein a material of the second buried layer is different from that of the semiconductor substrate.

According to one aspect of the present invention, the material of the second buried layer is different from that of the first buried layer.

According to one aspect of the present invention, the first buried layer is a buried insulator layer, and the second buried layer is a metal containing layer.

According to one aspect of the present invention, the first buried insulator layer comprises a thermal oxide layer and a deposited dielectric layer, and a bottom surface of the semiconductor island is fully isolated by first buried insulator layer.

According to one aspect of the present: invention, the semiconductor structure further comprises a vertically extended dielectric layer surrounding sidewalls of the semiconductor island.

According to one aspect of the present invention, a thermal conductivity of the second buried layer is higher than that of the semiconductor substrate.

Another embodiment of the present invention provides a semiconductor structure. The semiconductor structure includes a semiconductor substrate, a semiconductor island, a shallow trench isolation (STI) region, and a buried layer. The semiconductor substrate has an original surface. The semiconductor island is formed based on the semiconductor substrate. The shallow trench isolation (STI) region surrounds the semiconductor island. The buried layer is under the semiconductor island, wherein thermal conductivity of the buried layer is higher than that of the semiconductor substrate.

According to one aspect of the present invention, the buried layer is a metal containing layer r.

According to one aspect of the present invention, the buried layer includes a first portion extending into the STI region.

According to one aspect of the present invention, the STI region includes an oxide layer positioned under the first portion of the buried layer.

According to one aspect of the present invention, the STI region includes a dielectric layer positioned above the first portion of the buried layer.

Another embodiment of the present invention provides a semiconductor structure. The semiconductor structure includes a semiconductor substrate, a semiconductor island, a shallow trench isolation (STI) region, and a buried layer. The semiconductor substrate has an original surface. The semiconductor island is formed based on the semiconductor substrate. The shallow trench isolation (STI) region surrounds the semiconductor island. The buried layer is within the STI region and under the original surface of the semiconductor substrate, wherein the buried layer is distributed along a circumference of the semiconductor island, and a thermal conductivity of the buried layer is higher than that of the semiconductor substrate.

According to one aspect of the present invention, a top surface of the buried layer is lower than a bottom of the semiconductor island.

According to one aspect of the present invention, the buried layer includes a first portion right under the semiconductor island.

According to one aspect of the present invention, a localized insulator layer under the semiconductor island and above the buried layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1A is a flowchart illustrating a manufacture method of a localized SOZ (LSOZ) structure according to a first embodiment of the present invention.

FIG. 1B is a diagram illustrating Step 30 in FIG. 1A.

FIG. 2 is a diagram illustrating defining an active region of the localized SOZ (LSOZ) structure.

FIG. 3, FIG. 4, FIG. 5, FIG. 6A, FIG. 6B are diagrams illustrating FIG. 1B.

FIG. 7 is a flowchart illustrating a manufacture method of a localized SOZ (LSOZ) structure according to a second embodiment of the present invention.

FIG. 8, FIG. 9, FIG. 10, FIG. 11, FIG. 12 are diagrams illustrating FIG. 7.

FIG. 13 is a flowchart illustrating a manufacture method of a localized SOZ (LSOZ) structure according to a third embodiment of the present invention.

FIG. 14, FIG. 15, FIG. 16 are diagrams illustrating FIG. 13.

### DETAILED DESCRIPTION

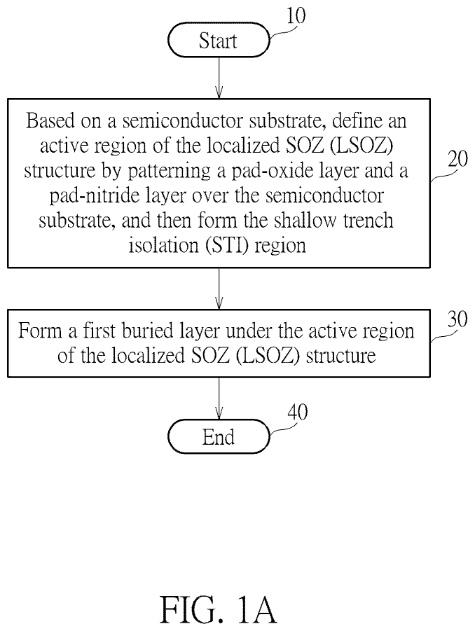

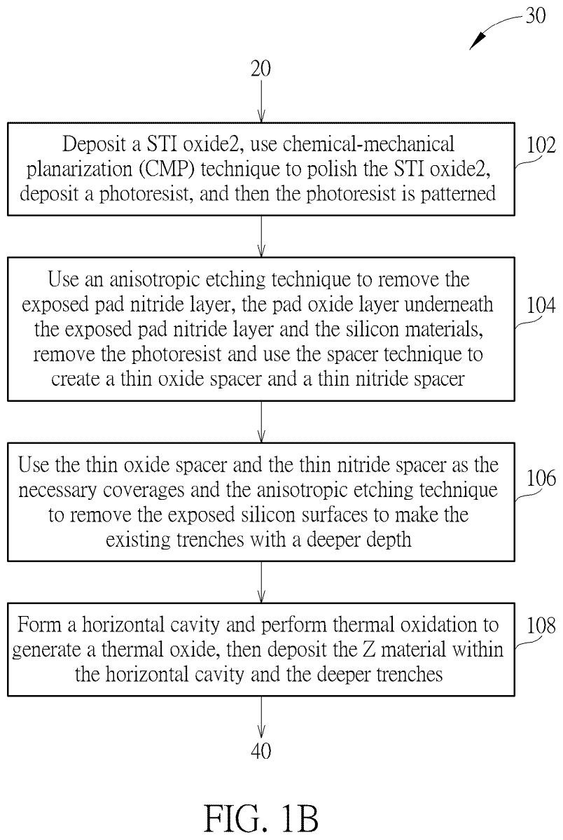

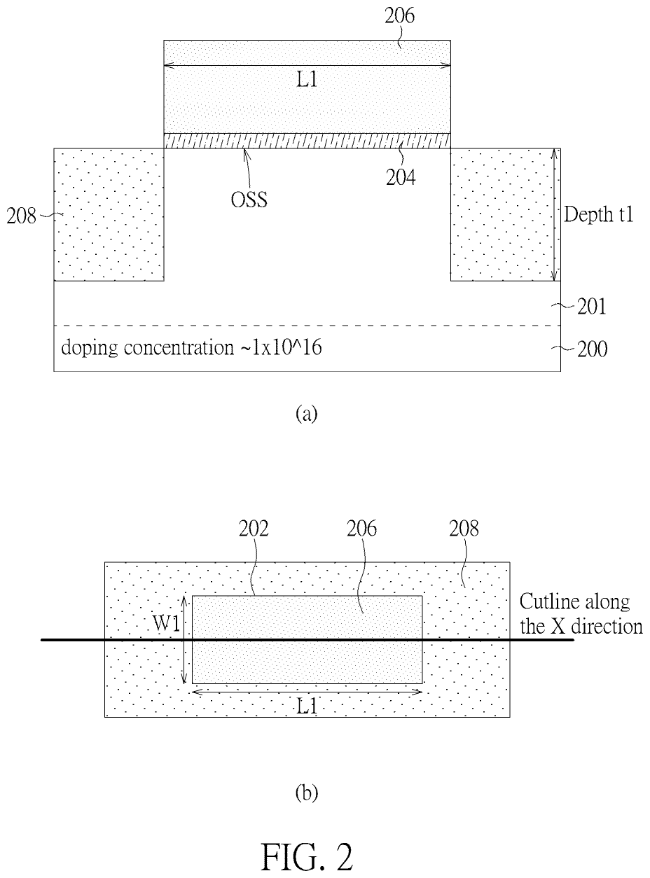

Please refer to FIG. 1A. FIG. 1A is a flowchart illustrating a manufacture method of a localized SOZ (LSOZ) structure according to a first embodiment of the present invention. Detailed Steps are as follows:
Step 10: Start.
Step 20: Based on a semiconductor substrate, define an active region of the localized SOZ (LSOZ) structure by patterning a pad-oxide layer 204 and a pad-nitride layer 206 over the semiconductor substrate, and then form the shallow trench isolation (STI) region 208 (FIG. 2).
Step 30: Form a first buried layer under the active region of the localized SOZ (LSOZ) structure.
Step 40: End.

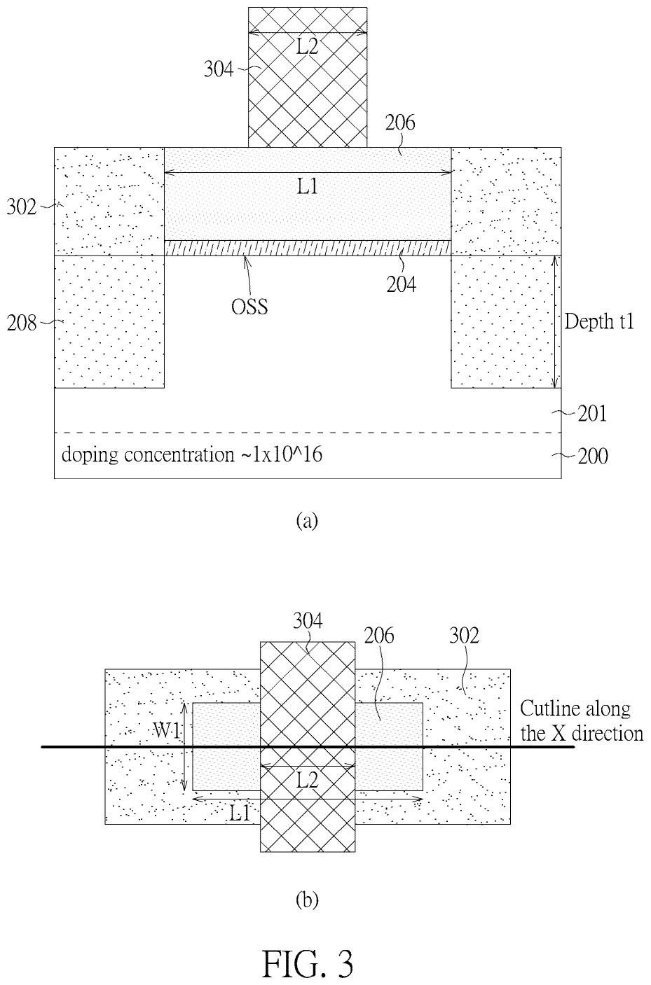

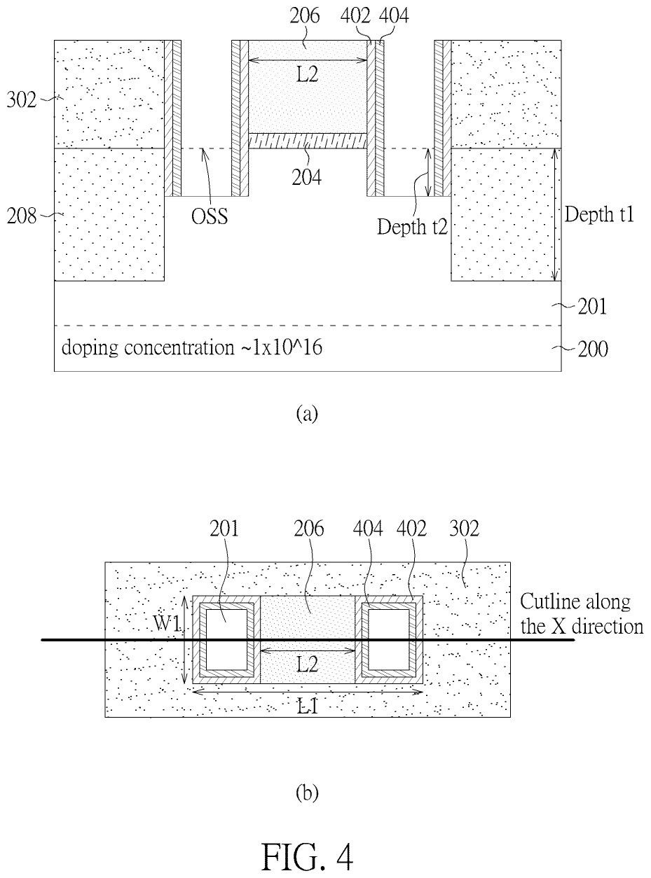

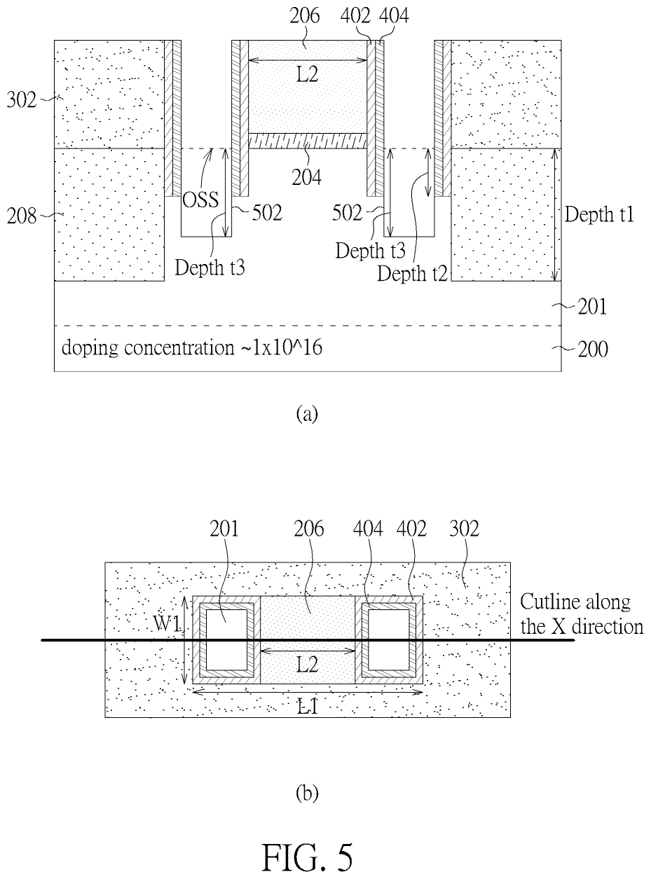

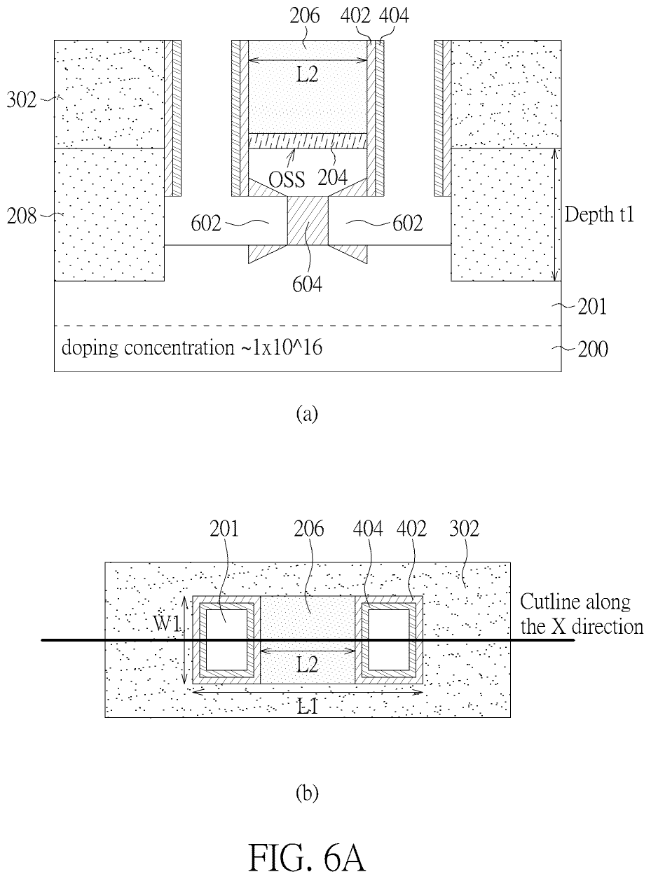

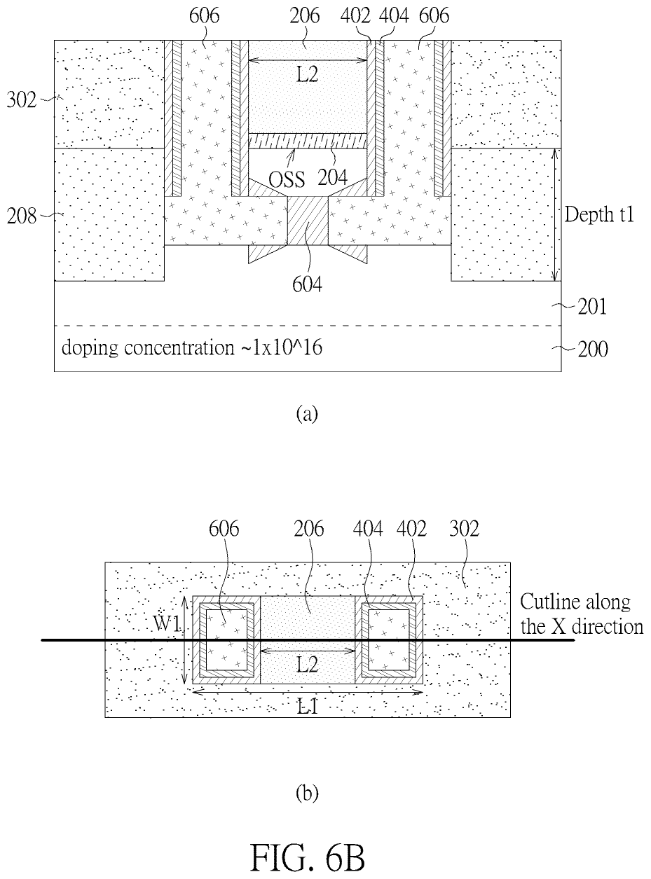

Please refer to FIG. 1B, FIG. 3, FIG. 4, FIG. 5, FIG. 6A, FIG. 6B. Step 30 could include:
Step 102: Deposit a STI oxide2 302, use chemical-mechanical planarization (CMP) technique to polish the STI oxide2 302, deposit a photoresist 304, and then the photoresist 304 is patterned (FIG. 3).
Step 104: Use an anisotropic etching technique to remove the exposed pad nitride layer 206, the pad oxide layer 204 underneath the exposed pad nitride layer 206 and the silicon materials, remove the photoresist 304 and use the spacer technique to create a thin oxide spacer 402 and a thin nitride spacer 404 (FIG. 4).
Step 106: Use the thin oxide spacer 402 and the thin nitride spacer 404 as the necessary coverages and the anisotropic etching technique to remove the exposed silicon surfaces to make the existing trenches with a deeper depth (FIG. 5).
Step 108: Form a horizontal cavity 602 and perform thermal oxidation to generate a thermal oxide 604, then deposit the Z material 606 within the horizontal cavity 602 and the deeper trenches (FIG. 6A).

### The First Embodiment

The following describes the processes to manufacture the LSOZ structure. In Step 20, as shown in FIG. 2(a), use a typical silicon wafer (either p-type or n-type) as the entire substrate, wherein the manufacture method starts with a well-designed doped p-type well 201, and the p-type well 201 is installed in a p-type substrate 200 (wherein in another embodiment of the present invention, could start with the p-type substrate 200, rather than starting with the p-type well 201). Then adopt the well-known process to create a rectangular active (single-crystalline silicon) region 202 (Length L1×Width W1) which is covered by a pad-oxide layer 204 and then a pad-nitride layer 206. Outside the active region 202, use the well-known techniques to form STI (shallow trench isolation) region 208 surrounding the active region 202, wherein the STI region 208 has the depth t1. In addition, FIG. 2(b) is a top view corresponding to FIG. 2(a), wherein FIG. 2(a) is a cross-section view along a cut line of an X direction shown in FIG. 2(b).

Then, in Step 102, as shown in FIG. 3(a), deposit the STI oxide2 302 to make a top surface of the STI oxide2 302 be leveled up to a top surface of the pad-nitride layer 206 (as one example). Use a photolithography technique and the photoresist 304 to define a well-designed region with L2 which is shorter than L1 so that the pad-nitride layer 206 on both left-hand side and right-hand side of the well-designed region are exposed. In addition, FIG. 3(b) is a top view corresponding to FIG. 3(a), wherein FIG. 3(a) is a cross-section view along a cut line of an X direction shown in FIG. 3(b).

Then, in Step 104, as shown in FIG. 4(a), use the anisotropic etching technique (e.g. RIE: Reactive Ion Etching) to remove the exposed pad nitride layer 206, the pad oxide layer 204 underneath the exposed pad nitride layer 206 and the silicon materials to create trenches into the silicon substrate regions (wherein the trenches have the depth t2 and the depth t2 is smaller than the depth t1). Then remove the photoresist 304 and use the spacer technique to create the thin oxide spacer 402 and the thin nitride spacer 404 on the exposed vertical edges of exposed silicon surface t2 and the other vertical edges of the STI (including the STI 208 and the STI oxide2 302). In addition, FIG. 4(b) is a top view corresponding to FIG. 4(a), wherein FIG. 4(a) is a cross-section view along a cut line of an X direction shown in FIG. 4(b).

Then, in Step 106, as shown in FIG. 5(a), use these spacers (the thin oxide spacer 402 and the thin nitride spacer 404) as the necessary coverages and the anisotropic etching technique to remove the exposed silicon surfaces to make the existing trenches with the deeper depth (depth t3). The sum of the depth t2 and the depth t3 is still smaller than the depth t1. As shown in FIG. 5(a), the exposed silicon surface 502 will be used to form the localized SOZ structure later. In addition, FIG. 5(b) is a top view corresponding to FIG. 5(a), wherein FIG. 5(a) is a cross-section view along a cut line of an X direction shown in FIG. 5(b).

Then, in Step 108, as shown in FIG. 6A (a), the horizontal cavity 602 is formed by thermal oxidation of the exposed silicon surface 502 and then etching such oxide, such that the horizontal cavity 602 surrounds the residual silicon. Thereafter, a thermal oxidation is performed such that all residual silicon is turned into the thermal oxide 604 (hereinafter, the neck thermal oxide). In addition, how to form the horizontal cavity 602 will be described later. In addition, FIG. 6A (b) is a top view corresponding to FIG. 6A (a), wherein FIG. 6A (a) is a cross-section view along a cut line of an X direction shown in FIG. 6A (b). Thereafter, the Z material 606 is deposited within the horizontal cavity 602 and the deeper trenches, as shown in 6B (a). FIG. 6B (b) is a top view corresponding to FIG. 6B (a), wherein FIG. 6B (a) is a cross-section view along a cut line of an X direction shown in FIG. 6B (b).

### The Second Embodiment

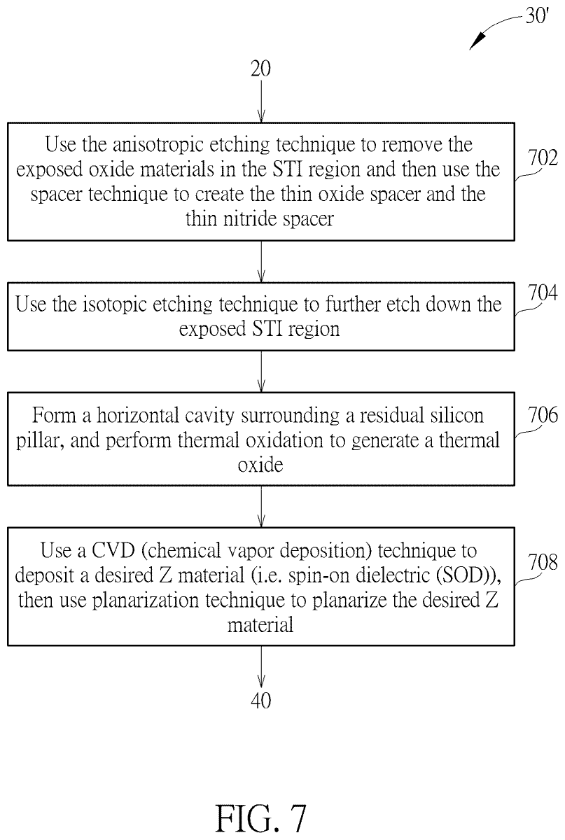

The following description is to elaborate more engineering techniques to form another revealed silicon surface structure which may be needed to make the localized SOZ structure have any desired pattern. Detailed Steps are as follows:
Step 10′: Start.
Step 20′: Based on a semiconductor substrate, define an active region of the localized SOZ (LSOZ) structure by patterning a pad-oxide layer 204 and a pad-nitride layer 206 over the semiconductor substrate, and then form the shallow trench isolation (STI) region 208 (FIG. 2).
Step 30′: Form a first buried layer under the active region of the localized SOZ (LSOZ) structure. (FIG. 7˜FIG. 12)
Step 40′: End.

Step 20′ is the same as the previous described Step 20, so the detail of which is skipped.

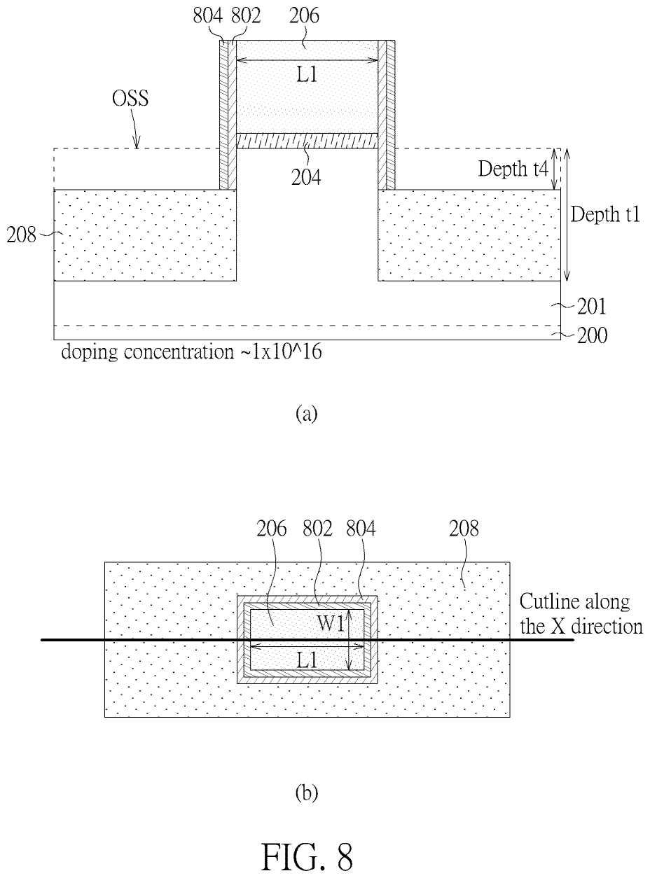

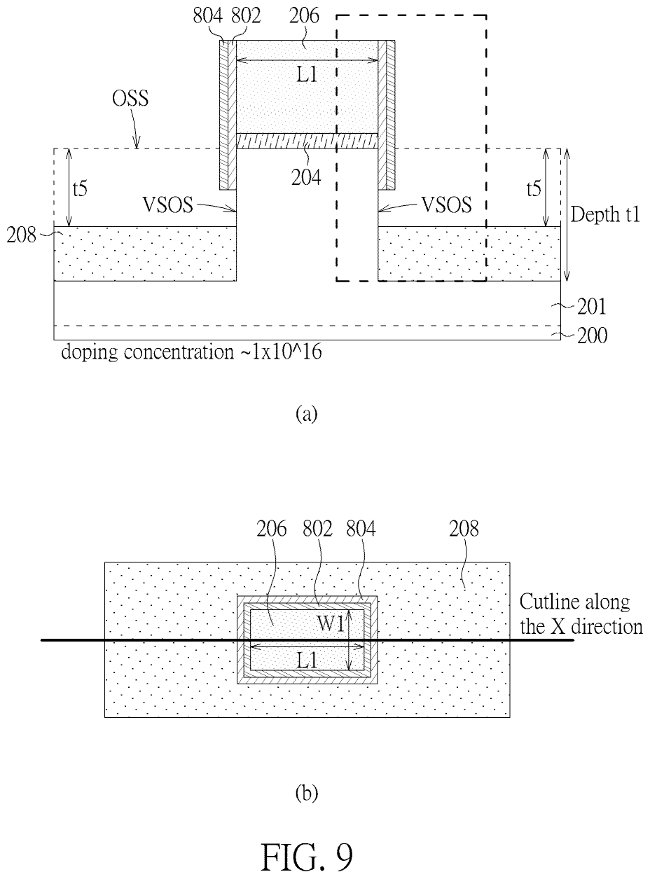

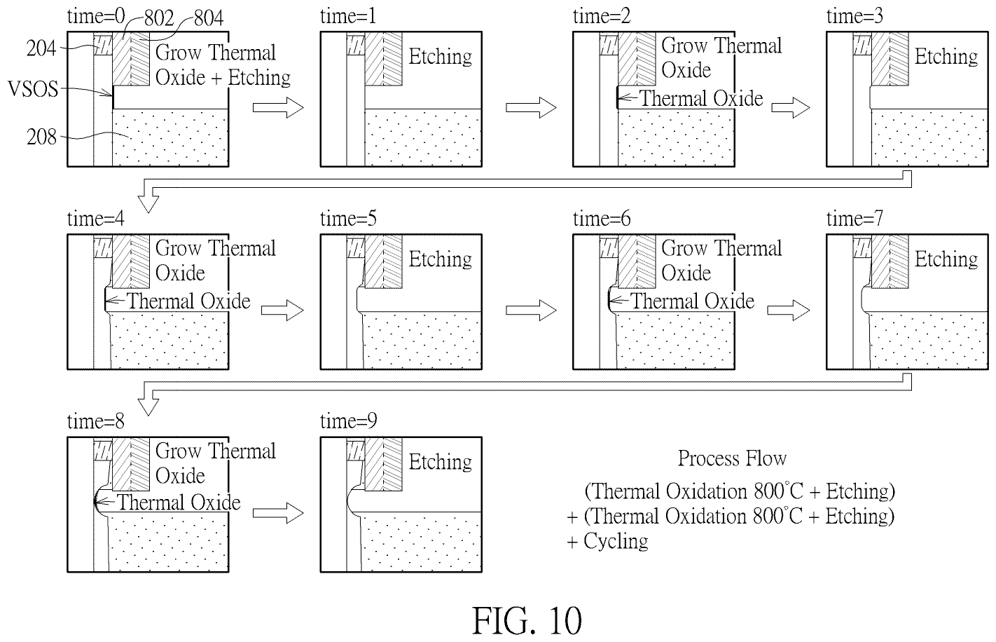

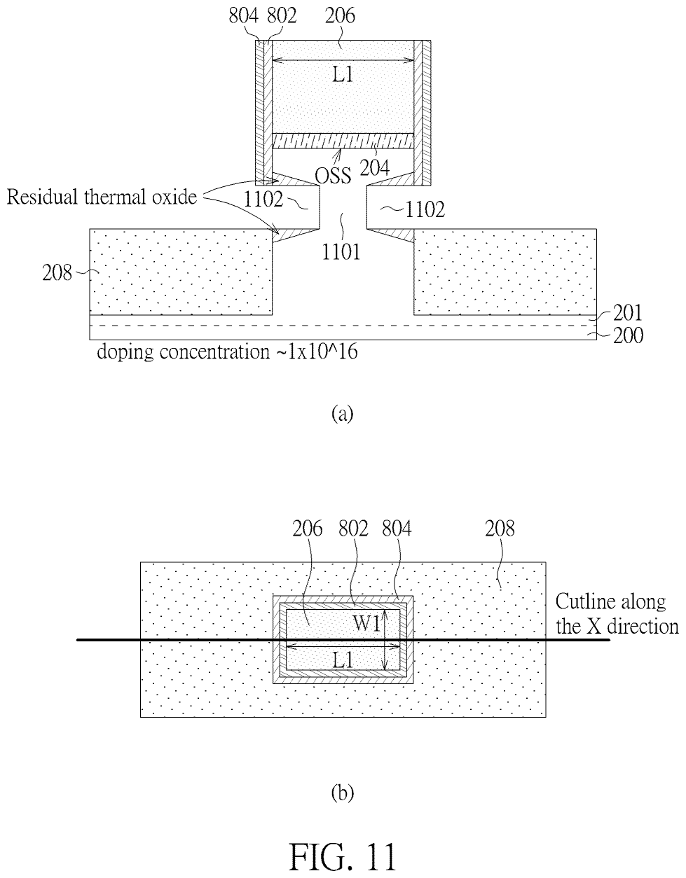

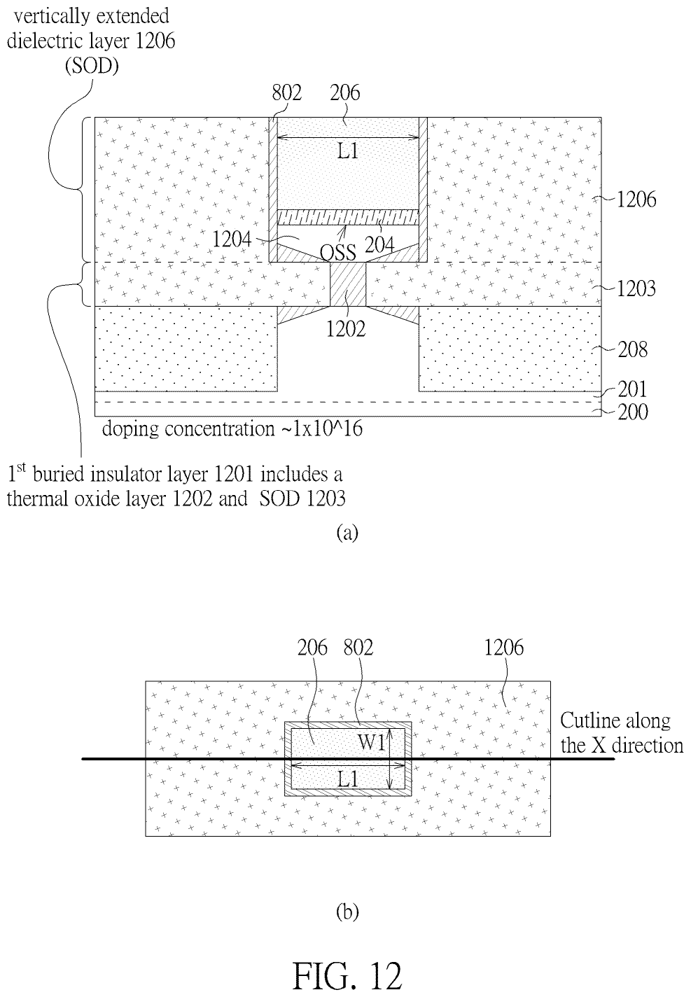

Next, please refer to Step 30′ and FIG. 7, FIG. 8, FIG. 9, FIG. 10, FIG. 11, FIG. 12. FIG. 7 is a flowchart illustrating a manufacture method of a localized SOZ (LSOZ) structure according to a second embodiment of the present invention, wherein Step 30′ described in FIG. 7 could include:
Step 702: Use the anisotropic etching technique to remove the exposed oxide materials in the STI region 208 and then use the spacer technique to create the thin oxide spacer 802 and the thin nitride spacer 804 (FIG. 8).
Step 704: Use the isotopic etching technique to further etch down the exposed STI region 208 (FIG. 9).
Step 706: Form a horizontal cavity 1102 surrounding a residual silicon pillar, and perform thermal oxidation to generate a thermal oxide 1202 (FIG. 10, FIG. 11 and FIG. 12).
Step 708: Use a CVD (chemical vapor deposition) technique to deposit a desired Z material (i.e. spin-on dielectric (SOD) 1203), then use planarization technique to planarize the desired Z material (FIG. 12).

Following FIG. 2, in Step 702, as shown in FIG. 8(a), then use the anisotropic etching technique (e.g. RIE: Reactive Ion Etching) to remove the exposed oxide materials in the STI region 208 by a well-measured distance with a depth t4 from the original semiconductor surface (OSS) of the semiconductor substrate. Then use the spacer technique to create the thin oxide spacer 802 and the thin nitride spacer 804 on the vertical edges of the pad-nitride layer 206, the pad-oxide layer 204 and the active region. In addition, FIG. 8(b) is a top view corresponding to FIG. 8(a), wherein FIG. 8(a) is a cross-section view along a cut line of an X direction shown in FIG. 8(b).

In Step 704, as shown in FIG. 9(a), then use the isotopic etching technique (either dry or wet species) to further etch down the exposed STI region 208 with a depth of t5 from the OSS. The key of this newly designed technology is described here: sidewalls of single-crystalline silicon regions below the thin oxide spacer 802 and the thin nitride spacer 804 but above a surface of the STI region 208 are exposed, that is, an vertical silicon sidewall with a depth of (t5−t4), called as VSOS (vertical silicon oxidation seed) region, is well exposed as the seed of the subsequent oxidation process. The rest areas of wafers are covered by either the pad-nitride layer 206 or the STI region 208 on the planar surface and are protected by the pad-nitride layer 206. The exposed silicon surface structure in FIG. 9(a), just like that in FIG. 5(a), will be used to form the localized SOZ later. In addition, FIG. 9(b) is a top view corresponding to FIG. 9(a), wherein FIG. 9(a) is a cross-section view along a cut line of an X direction shown in FIG. 9(b).

The following introduces a method to form a horizontal cavity to facilitate the formation of the localized SOZ. In Step 706, as shown in FIG. 10, a repeated oxidation/etching process is conducted with special designs over the VSOS region to remove most of the VSOS region. As shown in FIG. 10 which simulates, based on TCAD simulation by Sentaurus, the repeated oxidation/etching process against the exposed silicon surface VSOS within the structure corresponding to the dash rectangle in FIG. 9, at time=0, a thin thermal oxide is grown on the vertical silicon sidewall of the VSOS region at 800 degrees, and at time=1, the previously grown thermal oxide at time=0 is etched to reveal the silicon surface of the VSOS region. Again, at time=2, a thin thermal oxide is then grown on the revealed silicon sidewall of the VSOS region at 800 degrees, and at time=3, the previously grown thermal oxide at time=2 is etched to reveal the silicon surface of the VSOS. Such oxidation/etching process is repeated (at time=4˜time=9) until most of the VSOS region is removed and only a residual silicon pillar 1101 is left as shown in FIG. 11(a). Therefore, the horizontal cavity 1102 is formed and surrounds the residual silicon pillar 1101. Thereafter, a thermal oxidation is performed such that all residual silicon pillar 1101 is turned into thermal oxide 1202 (hereinafter, names as the neck thermal oxide), as shown in FIG. 12. Similarly, the exposed silicon surface structure in in FIG. 5(a) could be used to form the horizontal cavity 602 based on the processed introduced in FIG. 10, FIG. 11, FIG. 12. In addition, FIG. 11(b) is a top view corresponding to FIG. 11(a), wherein FIG. 11(a) is a cross-section view along a cut line of an X direction shown in FIG. 11(b).

Then, in Step 708, the CVD (chemical vapor deposition) technique is used to form the desired Z material to completely fill the horizontal cavity 1102, as shown in FIG. 12(a). For example, use CVD oxide fill-in process (many choices like high density deposited oxide, spin-on dielectric (SOD), etc.) to fill the horizontal cavity 1102 left by and wrap around the exposed silicon areas. Then, as shown in FIG. 12(a), use the planarization technique such as chemical-mechanical planarization (CMP), etch-back or else, to create a flat surface leveled up with the surface of either the pad-nitride layer 206 or the pad-oxide layer 204 (by assuming that the pad-nitride layer 206 was stripped already). Thus, an underlying oxide layer (with neck thermal oxide and SOD) is built up underneath the active region, and a desired silicon island 1204 (i.e. single-crystalline silicon island on insulator, SC-SIOI) is formed. In FIG. 12(a), the first buried insulator layer 1201 includes the thermal oxide 1202 (the neck thermal oxide) and the SOD 1203, and the vertically extended dielectric layer (also SOD) 1206 surrounds sidewalls of the silicon island 1208. In addition, FIG. 12(b) is a top view corresponding to FIG. 12(a), wherein FIG. 12(a) is a cross-section view along a cut line of an X direction shown in FIG. 12(b).

So a novel substrate-material structure is proposed here: there can be many SC-SIOI regions which are enclosed by oxide isolation layers surrounding the 6 surfaces of the single-crystalline silicon island (e.g. the silicon island 1204) which can be used as starting materials based on a bulk silicon substrate wafer without using an entire Sol wafer that is more expensive. The SC-SIOI structure can be well used as a substrate to house silicon transistors or other devices. Afterwards a MOSFET can be built into the SC-SIOI regions just like the state-of-the-art SOI device formation except without using an expensive entire SOI wafer, but such a SOI device is achieved by using a bulk wafer.

Of course, the localized SOI can be other Z material (such as, nitride) different from oxide/SOD as long as the horizontal cavity can be filled by using CVD technique or other processes. Of course, in another embodiment of the present invention, the thermal oxide 1202 derived from the residual silicon pillar 1101 in the first buried insulator layer 1201 of FIG. 12(a) could be etched and then replaced by other insulating material (such as nitride) during the CVD technique.

### The Third Embodiment

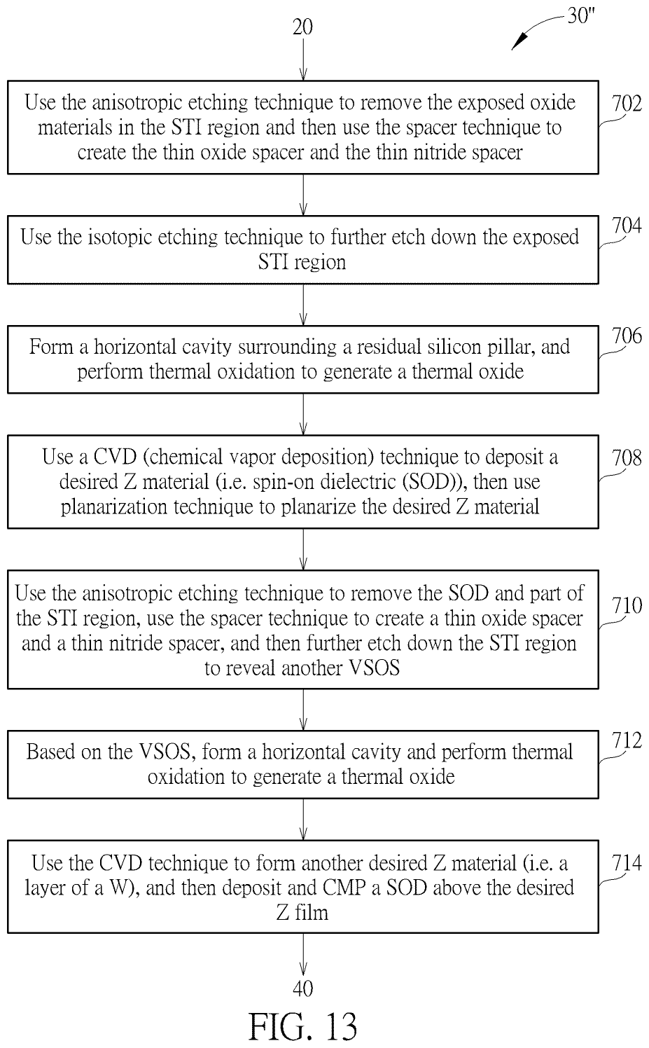

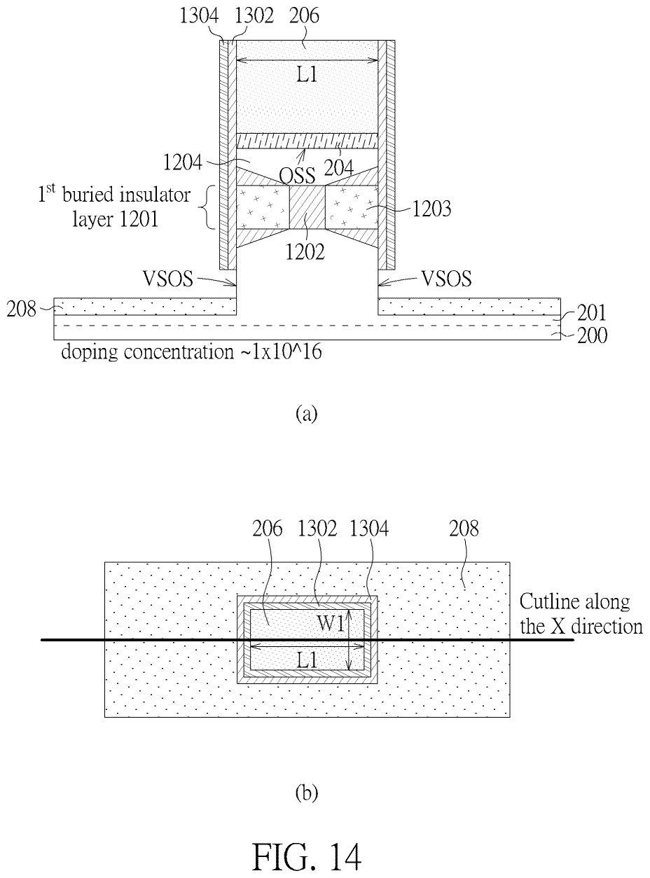

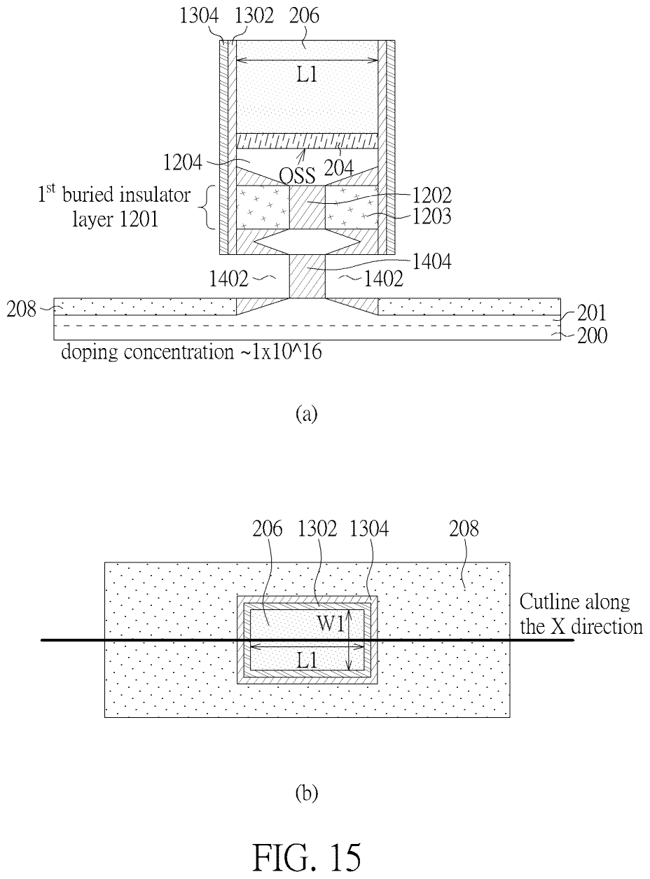

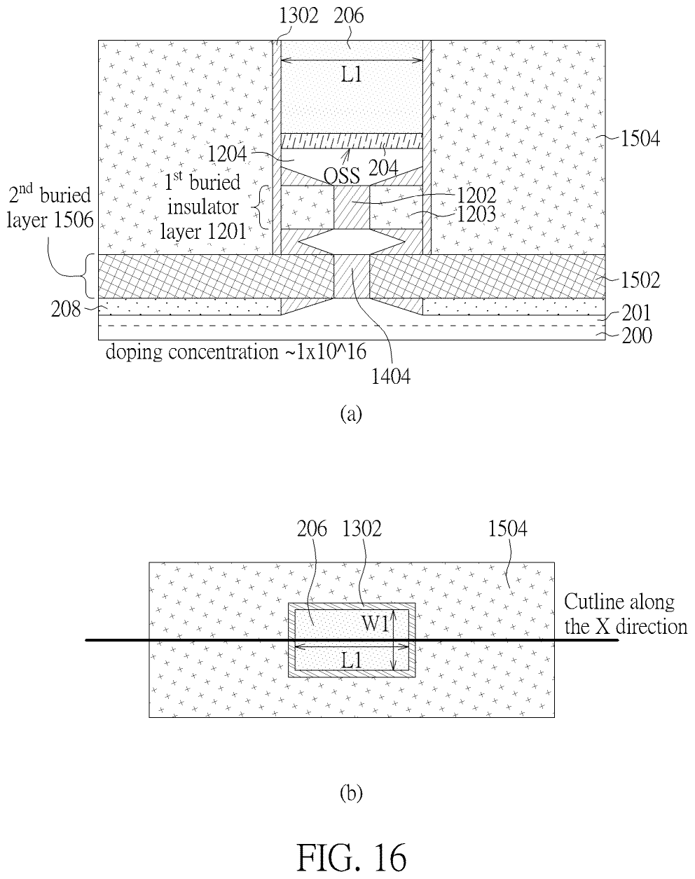

Next, please refer to FIG. 13, FIG. 14, FIG. 15, and FIG. 16. FIG. 13 is a flowchart illustrating a manufacture method of a localized SOZ (LSOZ) structure according to a third embodiment of the present invention, wherein Step 30″ described in FIG. 13 could include Step 702, Step 704, Step 706, Step 708, Step 710, Step 712, and Step 714, wherein Step 702, Step 704, Step 706, Step 708 can be referred to the above-mentioned corresponding descriptions and FIG. 8, FIG. 9, FIG. 10, FIG. 11 and FIG. 12, so further description thereof is omitted for simplicity.
Step 710: Use the anisotropic etching technique to remove the SOD and part of the STI region 208, use the spacer technique to create a thin oxide spacer 1302 and a thin nitride spacer 1304, and then further etch down the STI region 208 to reveal another VSOS (FIG. 14).
Step 712: Based on the VSOS, form a horizontal cavity 1402 and perform thermal oxidation to generate a thermal oxide 1404 (FIG. 15).
Step 714: Use the CVD technique to form another desired Z material (i.e. a layer of a W 1502), and then deposit and CMP a SOD 1504 above the desired Z film (FIG. 16).

In Step 710 which follows Step 708, as shown in FIG. 14(a), after the first buried insulator layer 1201 is formed in FIG. 12, use an anisotropic etching technique to remove the SOD (including the SOD 1203 and the vertically extended dielectric layer 1206) and part of the exposed STI region 208 by a well-measured distance. Then use the spacer technique to create the thin oxide spacer 1302 and the thin nitride spacer 1304 on the revealed vertical edges. Then, as shown in FIG. 14(a), the exposed STI region 208 is further etched down to expose another vertical silicon oxidation seed (VSOS), that is, an vertical silicon sidewall with a depth is well exposed as the seed of the subsequent oxidation process. In addition, FIG. 14(b) is a top view corresponding to FIG. 14(a), wherein FIG. 14(a) is a cross-section view along a cut line of an X direction shown in FIG. 14(b).

Then, in Step 712, as shown in FIG. 15(a), the repeated oxidation/etching process is conducted with special designs over the VSOS region to remove most of silicon material, just like the steps described in FIG. 10. Such oxidation/etching process is repeated until most of the silicon material is removed and only residual silicon pillar is left. Therefore, as shown in FIG. 15(a), the horizontal cavity 1402 is formed. Thereafter, a thermal oxidation is performed such that all residual silicon pillar is turned into the thermal oxide 1404 (hereinafter, named as the neck thermal oxide). In addition, FIG. 15(b) is a top view corresponding to FIG. 15(a), wherein FIG. 15(a) is a cross-section view along a cut line of an X direction shown in FIG. 15(b).

Then, in Step 716, as shown in FIG. 16(a), the Tungsten or other suitable high thermal conductivity material is deposited so that the layer of the W 1502 over the etched down STI region 208 is achieved. For example, following the thermal oxide 1404 (i.e. the neck thermal oxide) is formed, directly use CVD Tungsten or other material to fill completely the horizontal cavity 1402, and then the additional SOD 1504 is deposited and CMP. Thus, the second buried layer 1506 (including the thermal oxide 1404 and the W 1502) is formed and under the first buried insulator layer 1201. Under the silicon island 1204, the first buried insulator layer 1201 is an insulating layer to isolate the silicon island 1204, and the second buried layer 1506 with metal (such as Tungsten) provides better thermal dissipation as compared with semiconductor substrate. Therefore, a heterogeneous wafer substrate with doubled buried layers is completed. Additionally, the backside of the semiconductor substrate could be polished by CMP (chemical-mechanical planarization) to reveal the second buried layer 1506 which then could play as a supporting substrate. That is, a CMP technique can be used from the backside of the wafer to make a thinning wafer with strong supporting structure so that the wafer thickness can be thinner than 50 microns or even less. In addition, FIG. 16(b) is a top view corresponding to FIG. 16(a), wherein FIG. 16(a) is a cross-section view along a cut line of an X direction shown in FIG. 16(b).

Afterwards, typical processes can be continued to complete a planar surface of active regions in multiple ways; a variety of embodiments can be used to complete a crystalline substrate area for making different kinds of transistors with various gate structures such as planar-gate, FinFET, Tri-Gate, GAA or Gate Around structure, Sheet-channel or Tube-channel which are achieved based on the needs and their respective formation processes. The SC-SIOI devices have shown the feasibility and implementation by using less expensive bulk silicon wafer substrate instead of using an entire SOI wafer that is more expensive.

Although the present invention has been illustrated and described with reference to the embodiments, it is to be understood that the invention is not to be limited to the disclosed embodiments, but on the contrary, is intended to cover various modifications and equivalent arrangements included within the spirit and scope of the appended claims.

What is claimed is:

1. A semiconductor structure, comprising:
a semiconductor substrate with an original surface;
a semiconductor island formed based on the semiconductor substrate;
a shallow trench isolation (STI) region surrounding the semiconductor island;
a first buried layer being a localized layer under the semiconductor island, wherein a material of the first buried layer is different from that of the semiconductor substrate; and
a second buried layer being a localized layer under the first buried layer, wherein a material of the second buried layer is different from that of the semiconductor substrate.

2. The semiconductor structure in claim 1, wherein the material of the second buried layer is different from that of the first buried layer.

3. The semiconductor structure in claim 2, wherein the first buried layer is a buried insulator layer, and the second buried layer is a metal containing layer.

4. The semiconductor structure in claim 3, wherein the first buried insulator layer comprises a thermal oxide layer and a deposited dielectric layer, and a bottom surface of the semiconductor island is fully isolated by first buried insulator layer.

5. The semiconductor structure in claim 4, further comprising a vertically extended dielectric layer surrounding sidewalls of the semiconductor island.

6. The semiconductor structure in claim 1, wherein a thermal conductivity of the second buried layer is higher than that of the semiconductor substrate.

7. A semiconductor structure, comprising:
a semiconductor substrate with an original surface;
a semiconductor island formed based on the semiconductor substrate;
a shallow trench isolation (STI) region surrounding the semiconductor island; and
a buried layer under the semiconductor island, wherein thermal conductivity of the buried layer is higher than that of the semiconductor substrate.

8. The semiconductor structure in claim 7, wherein the buried layer is a metal containing layer.

9. The semiconductor structure in claim 7, wherein the buried layer comprises a first portion extending into the STI region.

10. The semiconductor structure in claim 9, wherein the STI region comprises an oxide layer positioned under the first portion of the buried layer.

11. The semiconductor structure in claim 10, wherein the STI region comprises a dielectric layer positioned above the first portion of the buried layer.

12. A semiconductor structure, comprising:
a semiconductor substrate with an original surface;
a semiconductor island formed based on the semiconductor substrate;
a shallow trench isolation (STI) region surrounding the semiconductor island; and
a buried layer within the STI region and under the original surface of the semiconductor substrate, wherein the buried layer is distributed along a circumference of the semiconductor island, and a thermal conductivity of the buried layer is higher than that of the semiconductor substrate.

13. The semiconductor structure in claim 12, wherein a top surface of the buried layer is lower than a bottom of the semiconductor island.

14. The semiconductor structure in claim 12, wherein the buried layer comprises a first portion right under the semiconductor island.

15. The semiconductor structure in claim 14, wherein a localized insulator layer under the semiconductor island and above the buried layer.
